(19) United States
(12) Patent Application Publication
(10) Pub. No.: US 2006/0081357 A1
(43) Pub. Date: Apr. 20, 2006

(54) Radiation module

(76) Inventors: Wen-Hao Liu, Taipei (TW); Chu-Hsien Chou, Taipei (TW)

Correspondence Address: G. LINK CO., LTD, 3550 BELL ROAD, MINOOKA, IL, 60447, US

(21) Appl. No.: 10/968,108

(22) Filed: Oct. 20, 2004

(51) Int. Cl. H05K 7/20

(52) U.S. Cl. 165/80.3; 165/121; 361/697

(57) ABSTRACT

A radiation module comprises a rectangular radiator and a fan. The rectangular radiator provides two long lateral sides and two short lateral sides, The fan is attached to the radiator and has an annular frame with a fan wheel being received therein. The annular frame has a plurality of engaging part at the periphery thereof and a flow passage therein. The annular frame is fixed to the radiator with the engaging parts engaging with the radiator such that part of the flow passage extends beyond the long lateral sides to form two outer sections for fluid flowing outward directly via the outer sections.

### BACKGROUND OF THE INVENTION

1. Field of the Invention

The present invention is related to a radiation module and particularly to a fan and radiator for heat dissipation.

2. Brief Description of the Related Art

Due to electronic components being kept updated and the users keeping to create new demands, problem of heat generation occurs along with effect, treating speed and power being enhanced too.

Especially in the computer, North bridge chips is easy to produce high temperature too while the performance is enhanced in addition to the central processing unit (CPU) on the main board. The performance of preceding heat generating components is affected seriously if the heat is not removed rapidly and even the life spans thereof becomes shorter accordingly. In order to remove the heat from preceding heat generating components and achieve best performance thereof and prolong the life spans thereof, a heat dissipation device is usually used to attain purpose of heat dissipation. The most popularly used heat dissipation device is the fan and the radiator because of their being conveniently used and lower costs. This is why the manufacturers are interested in developing and researching the fan and the radiator.

Referring to FIGS. 1 to 3, a conventional fan includes a fan frame 11 and a fan wheel 12. The fan is attached to the radiator 13. The fan frame 11 has a circular flow passage 114 at the center thereof and there are perforations 111 in the fan frame 11. The fan wheel 12 is received in the flow passage 114 and fan frame 11 is fastened to the radiator 13 by way of the fastening screws 17 passing through the perforations 111.

Referring to FIG. 4 in company with FIG. 3, when the fan wheel 12 rotates, fluid is dragged to flow and blown to the radiator 13 via the circular passage. Then, the fluid is dispersed after passing through the air clearances 131 such that heat from CPU 15 can be carried outward. However, the fluid dragged by the conventional fan only moves to the radiator 13 and many heat generation components 16 such as coil sets, North Bridge chip and etc. surrounding the radiator 13 are incapable of receive fluid from the fan so that unfavorable heat dissipation is obtained to result in lower heat dissipation efficiency.

Further, the fan frame 11 is square with the circular flow passage 114 and there are larger abundant space beside the circular flow passage 114 such that the radiator under the fan frame 11 is unable to be covered by the circular flow passage 114 and it results in less fluid reaching the radiator 13. In this way, the effect of convection is affected to lead unfavorable heat dissipation effect.

### SUMMARY OF THE INVENTION

An object of the present invention is to provide a radiation module in which a fan with an annular frame is attached to a rectangular radiator and the annular frame extends beyond two long lateral sides of the radiator to form two outer sections for the fluid flowing through the outer sections and enhancing cooling effect of heat generating components surrounding the radiator.

Another object of the present invention is to provide a radiation module in which a fan with an annular frame is attached to a rectangular radiator and a flow zone of the annular frame is formed along longitudinal direction of the radiator so as to increase acted area of radiator with the fan.

A further object of the present invention is to provide a radiation module in which a fan with an annular frame is attached to a square radiator and the annular frame extends beyond four lateral sides of the radiator to form four outer sections for the fluid flowing through the outer sections and enhancing cooling effect of heat generating components surrounding the radiator.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of the conventional fan associated with radiator,

FIG. 2 is an assembled perspective view of the conventional fan associated with radiator shown in FIG. 1;

FIG. 3 is a top view of the conventional fan associated with radiator,

FIG. 4 is a sectional view of the conventional fan associated with radiator illustrating movement thereof;

FIG. 5 is an exploded perspective view of the first embodiment according to the present invention;

FIG. 6 is an assembled perspective view of the first embodiment according to the present invention;

FIG. 7 is a top view of the first embodiment according to the present invention;

FIG. 8 is a sectional view of the first embodiment according to the present invention illustrating movement thereof;

FIG. 9 is an exploded perspective view of the second embodiment according to the present invention;

FIG. 10 is a perspective view of an exploded perspective view of the second embodiment according to the present invention;

FIG. 11 is atop view of the second embodiment according to the present invention; and

FIG. 12 is a sectional view of the second embodiment according to the present invention illustrating movement thereof

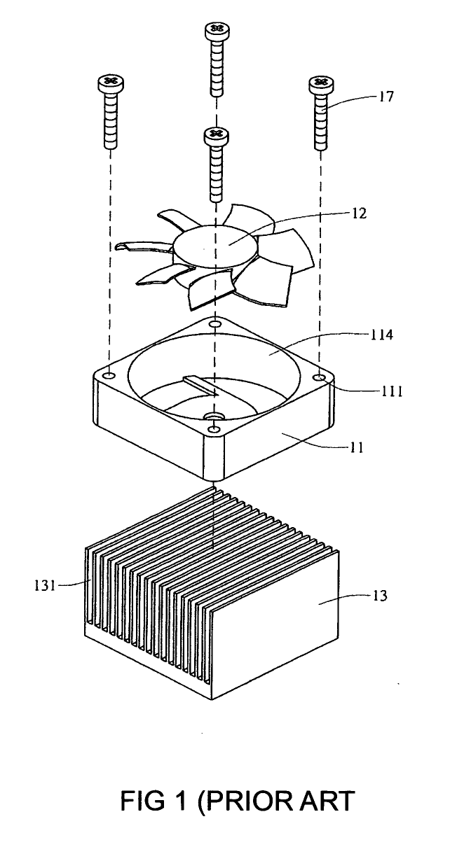

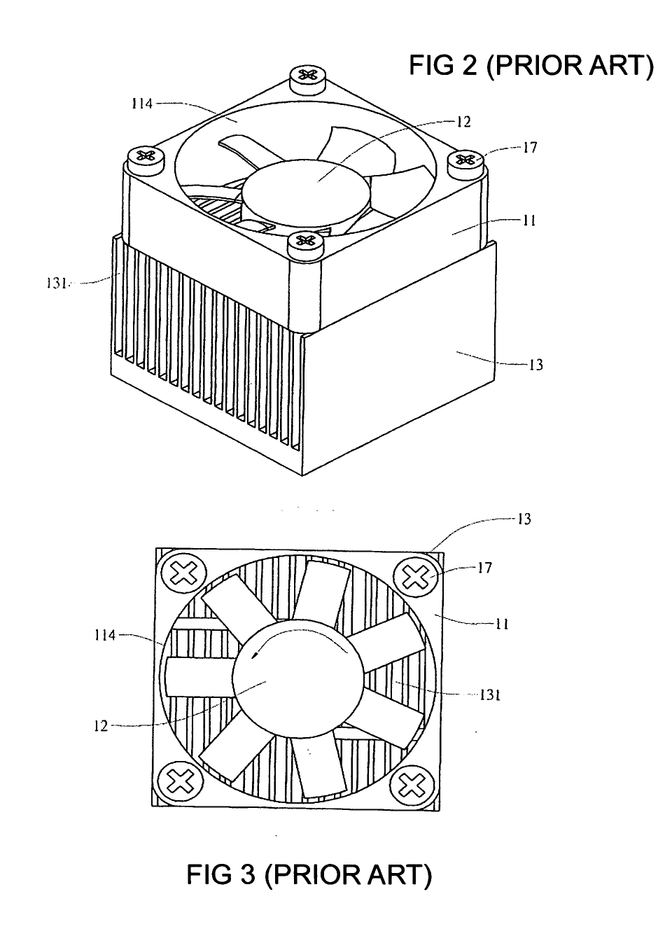

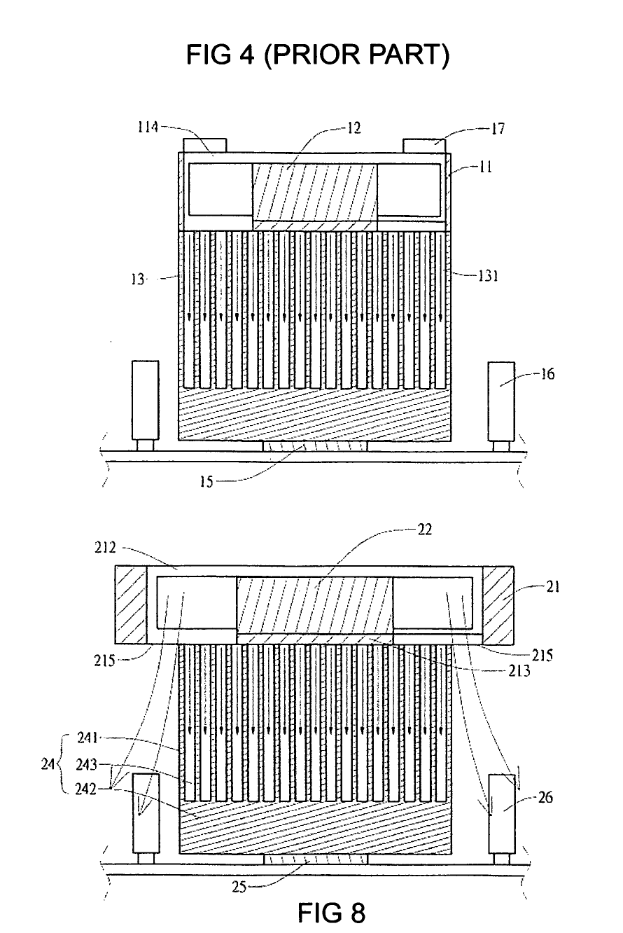

### DETAILED DESCRIPTION OF THE PREFERRED EMBODIMENT

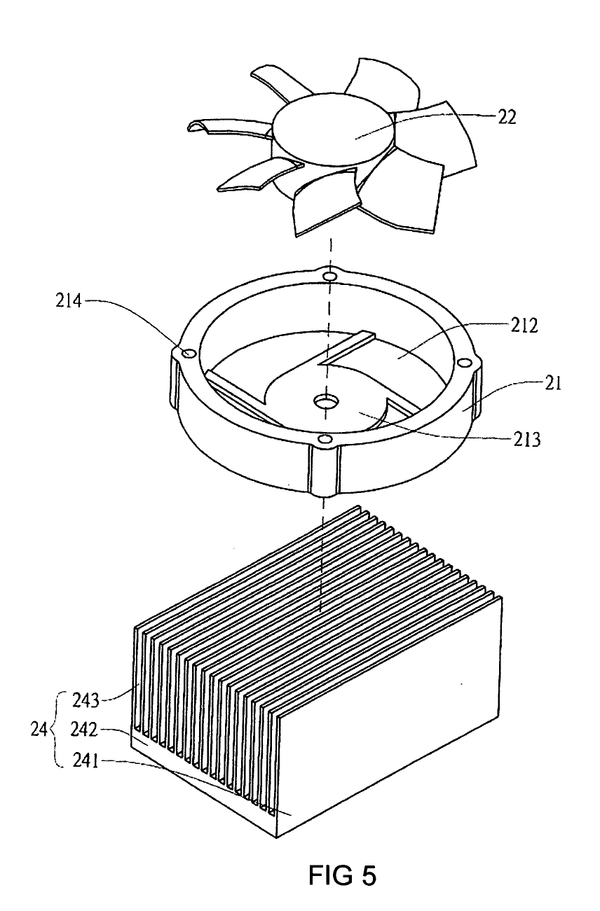

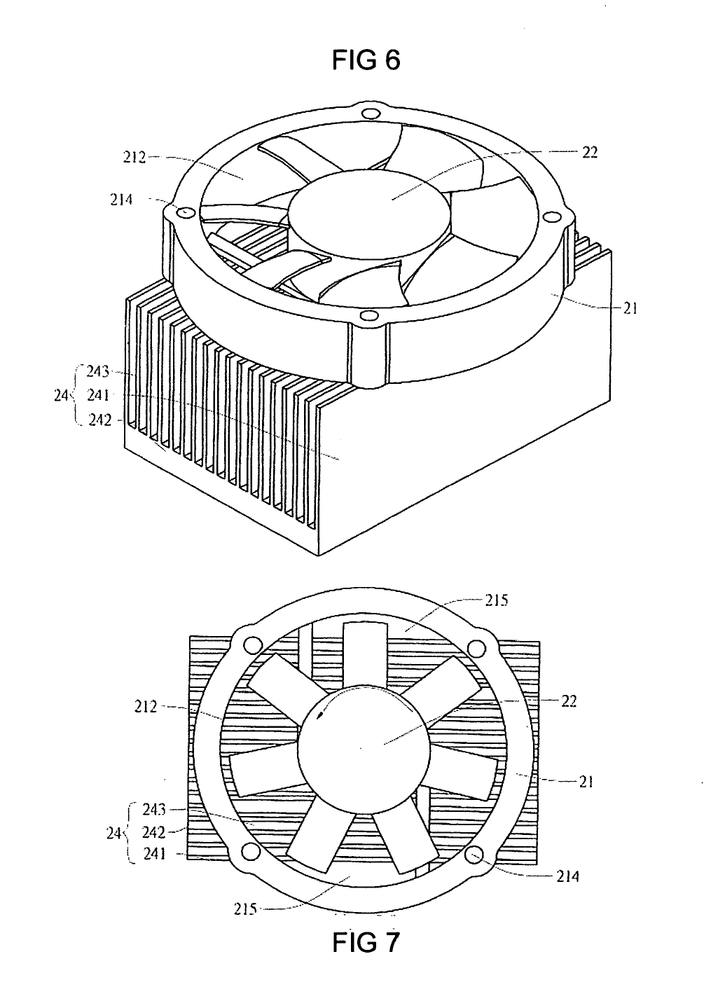

Referring to FIGS. 5, 6 and 7, the first embodiment of a radiation module according to the present invention includes a fan associated with rectangular radiator 11. The rectangular radiator 24 has long sides 241, short sides 242 and a plurality of air clearance 243. The fan includes an annular frame 21 and a fan wheel 22. The annular frame 21 is provided with a flow passage 212 available for flowing fluid and has a hub seat 213 therein. There are fastening parts 214 at the annular frame 21. The fan wheel 22 is disposed in the annular frame 21 and attached to the hub seat 213 and the annular frame 21 is attached to the radiator 24 by way of the fastening parts 214 such that the flow passage can extend beyond the long sides 241 of the radiator 24 to form two outer sections 215.

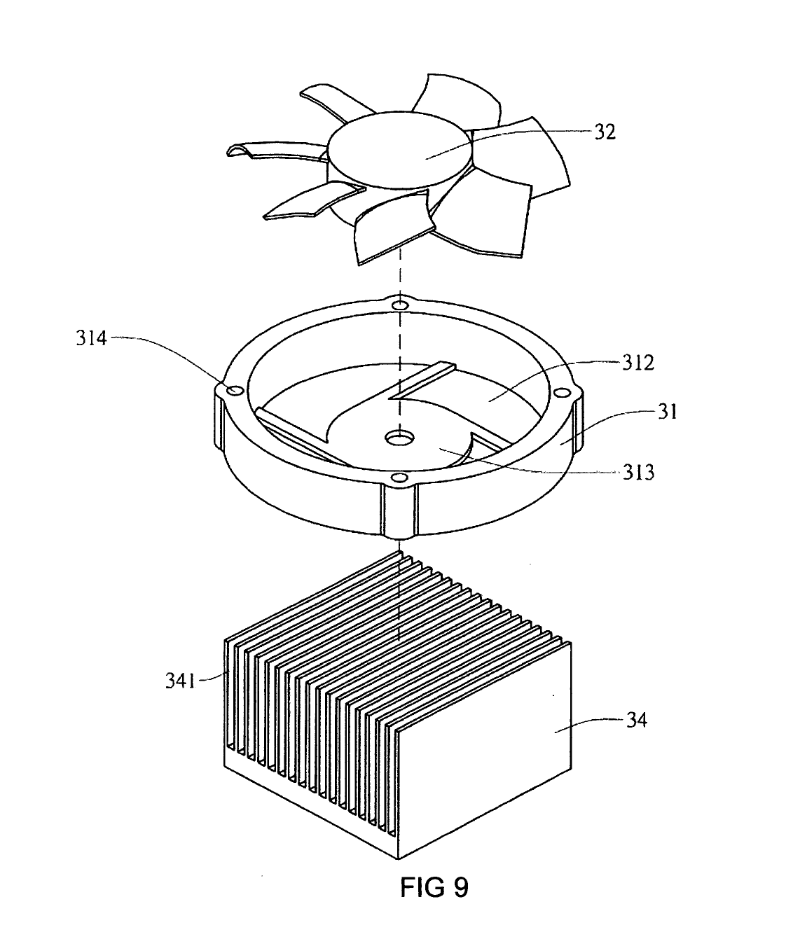

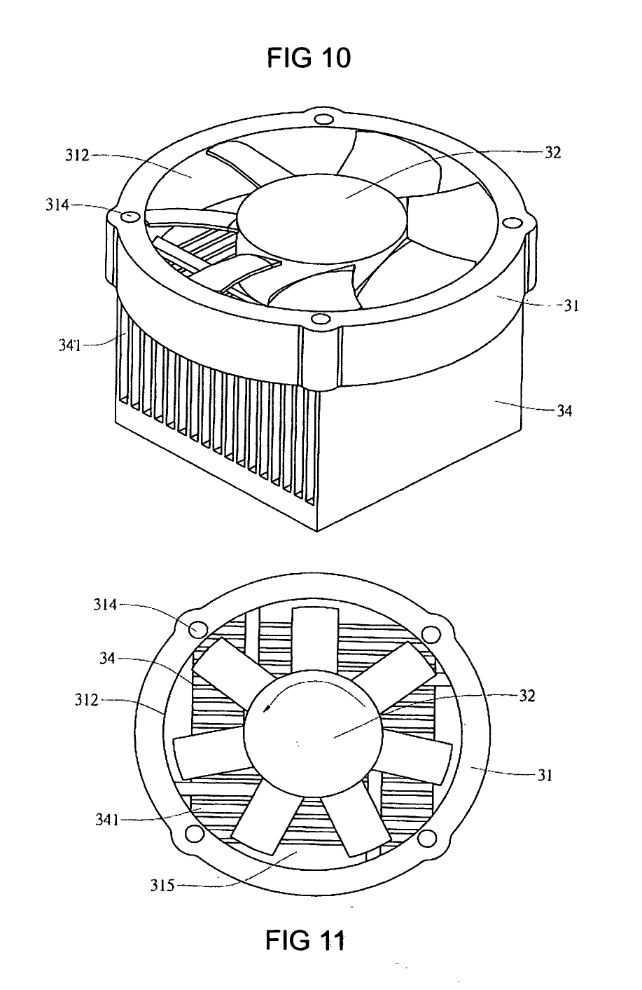

Referring to FIGS. 7 and 8, when the fan wheel 22 rotates to drag the fluid blowing toward the radiator 24 via the flow passage 212 and the fluid dispersing outward through the air clearance 243 to carry heat generated from the central processing unit (CPU) out. The fluid, which moves along the flow passage 212, can blow downward to reach heat generating components 26 beside the radiator 24 and assist heat dissipation of the heat generating components 26.

Further, the annular frame 21 constitutes flow zone at the longitudinal direction of the radiator 24 to increase the contact area of the radiator 24 with fluid blown with the fan 21 so as to overcome deficiency of the radiator being unable to contact with the fluid effectively and enhance the overall heat dissipation efficiency.

Referring to FIGS. 9,10 and 11, the second embodiment of the present invention is illustrated. The radiation module in the second embodiment includes a fan and a square radiator 34. The fan further includes an annular frame 31 and a fan wheel 32. The annular frame 31 is provided with a flow passage 312 available for flowing fluid and has a hub seat 313 therein. There are fastening parts 314 at the annular frame 31. The fan wheel 32 is disposed in the annular frame 21 and attached to the hub seat 313 and the annular frame 31 is attached to the radiator 34 by way of the fastening parts 314 engaging with the radiator 34 such that the flow passage 312 can extend beyond four sides of the radiator 34 to form four outer sections 315.

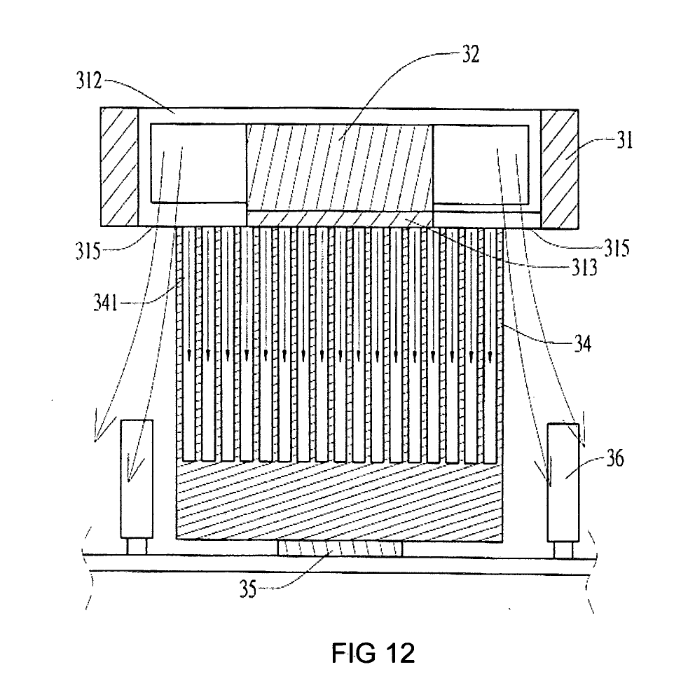

Referring to FIGS. 11 and 12, when the fan wheel 32 rotates to drag the fluid blowing toward the radiator 34 via the flow passage 312 and the fluid dispersing outward through the air clearance 341 to carry heat generated from the central processing unit (CPU) 35 out. The fluid, which moves along the flow passage 312, can blow downward to reach heat generating components 36 beside the radiator 24 and assist for dissipating heat of the heat generating components 36.

When the axial flow fan is assembled, the hub member 131 is movably connected to the driving device 12 and the fan blade part 13 is movably connected to the frame 11. The fan blades 132 of the fan blade part 13 are disposed outside the frame 11 and lower edges of the fan blades are flush with the upper edge of the frame 11.

While the invention has been described with referencing to preferred embodiments thereof, it is to be understood that modifications or variations may be easily made without departing from the spirit of this invention, which is defined by the appended claims.

1. A radiation module capable of cooling electronic components beside the radiator module, comprising:
a rectangular radiator, being composed of a plurality of upstanding cooling fins and providing two long lateral sides and two short lateral sides; and
a fan, being attached to the radiator, having an annular frame with a fan wheel being received therein, the annular frame having four engaging holes being disposed at the periphery thereof in a way of spacing apart an equal circular distance to each other for being engaged to the top of the radiator;
characterized in that the annular frame has an inner diameter greater than a distance between the two short lateral sides of the radiator and a circular portion of the annular frame, which is slightly less than a circular distance between two neighboring ones of the engaging holes, extending outward from each of the two short lateral sides respectively such that an outer flow passage is formed between the annular frame and the respective short lateral side and air dragged downward by the fan wheel is capable of passing through the flow passage for cooling the electronic components in addition to a central processing unit directly disposed at the bottom of the radiator.

2. (canceled)

3. A radiation module capable of cooling electronic components beside the radiator module, comprising:
a square radiator with four equal lateral sides, providing a plurality of upstanding cooling fins; and
a fan, being attached to the radiator, having an annular frame with a fan wheel being received therein, the annular frame having four engaging holes being disposed at the periphery thereof in a way of spacing apart an equal circular distance to each other for being engaged to the top of the radiator;
characterized in that the annular frame has an inner diameter greater than a distance between two opposite lateral sides of the radiator and a circular portion of the annular frame, which is slightly less than a circular distance between two neighboring ones of the engaging holes, extends outward from each of the lateral sides respectively such that an outer flow passage is formed between the annular frame and the respective lateral side and air dragged downward by the fan is capable of passing through the outer flow passage for cooling the electronic components in addition to the central processing unit directly disposed at the bottom of the radiator.

4. (canceled)
